(19) United States
(12) Patent Application Publication
(10) Pub. No.: US 2020/0075662 A1
(43) Pub. Date: Mar. 5, 2020

(54) IMAGE SENSORS, FORMING METHODS OF THE SAME, AND IMAGING DEVICES

(71) Applicant: HuaiAn Imaging Device Manufacturer Corporation, Huaian (CN)

(72) Inventors: Zengzhi Huang, Huaian (CN); Haifeng Long, Huaian (CN); Lingyun Ni, Huaian (CN); Tianhui Li, Huaian (CN); Xiaolu Huang, Huaian (CN)

(73) Assignee: HuaiAn Imaging Device Manufacturer Corporation, Huaian (CN)

(21) Appl. No.: 16/383,589

(22) Filed: Apr. 13, 2019

(30) Foreign Application Priority Data
Aug. 31, 2018 (CN) 201811006618.3

(51) Int. Cl. H01L 27/146

(52) U.S. Cl. CPC H01L 27/14643; H01L 27/14685; H01L 27/14621; H01L 27/14627

(57) ABSTRACT

The present disclosure relates to an image sensor and a method of forming the same, and an image forming device. An image sensor includes: a substrate in which a photosensitive element region is formed; and a first light concentrating portion formed in a peripheral region of the photosensitive element region, wherein the first light concentrating portion is formed such that to the light entering the peripheral region of the photosensitive element is refracted toward the photosensitive element region through the light concentrating portion. The image sensor and method for forming an image sensor of the present disclosure allow more light to enter the area of the photosensitive element in the substrate, thereby improving the light sensitivity of the image sensor.

### RELATED APPLICATION

This application claims priority to Chinese Application number CN201811006618.3, filed on Aug. 31, 2018, entitled “IMAGE SENSORS, FORMING METHODS OF THE SAME, AND IMAGING DEVICES,” the content of which is incorporated herein by reference in its entirety.

### TECHNICAL FIELD

The present disclosure relates to the field of semiconductors, and particularly to an image sensor and a method of forming the same, and an imaging device including the image sensor.

### BACKGROUND

An image sensor is an electronic device for converting an optical image focused on an image sensor into an electrical signal. The image sensor can be used for an imaging device such as a digital camera such that light received by the imaging device is converted into a digital image. Commonly used image sensors include complementary metal oxide semiconductor (CMOS) image sensors (CIS) and charge coupled device (CCD) sensors, which are widely used in various imaging applications, such as digital cameras or cell phone camera.

Whether it is CCD or CMOS, the image sensor uses the photosensitive element as the basic means of image capturing. The core of the photosensitive element may be a photodiode. The photosensitive element may absorb the light incident on the photosensitive element after being irradiated with light so that carriers are generated to generate an electrical signal. Then, the signal obtained from the light is restored by the processor, so that a color image may be obtained.

Currently, there is a need for new technologies to improve the light sensitivity of image sensors.

### SUMMARY

It is an objective of the present disclosure to improve the light sensitivity of an image sensor.

According to an aspect of the present disclosure, an image sensor is provided. The image sensor includes: a substrate including a photosensitive element region; and a first light concentrating portion in a peripheral region of the photosensitive element region, wherein the first light concentrating portion is formed such that light entering the peripheral region is refracted towards the photosensitive element region through the first light concentrating portion.

According to another aspect of the present disclosure, a method for forming an image sensor is provided. The method includes: providing a substrate including a photosensitive element region; and forming a first light concentrating portion in a peripheral region of the photosensitive element region, wherein the first light concentrating portion is formed such that light entering the peripheral region of the photosensitive element is refracted towards the photosensitive element region.

In accordance with still another aspect of the present disclosure, an imaging device including the image sensor described herein is provided.

Other features and advantages of the present disclosure are better understood from the following detailed description of exemplary embodiments.

### BRIEF DESCRIPTION OF THE DRAWINGS

The accompanying drawings, which are portion of the specification, describe embodiments of the present disclosure and, together with the specification, are used to explain the principles of the present disclosure.

The present disclosure can be more clearly understood from the following detailed description in accordance with accompanying drawings, in which:

FIG. 1 is a schematic view that schematically showing the configuration of a conventional image sensor in the form of a sectional view.

FIG. 2 is a schematic view that schematically showing a transmission path of a part of light in the image sensor of FIG. 1.

FIG. 3 is a schematic view that schematically showing a configuration of an image sensor of an exemplary embodiment of the present disclosure and a transmission path of light therein in the form of a cross-sectional view.

FIG. 4 is a schematic view that schematically showing an angular arrangement of a light concentrating portion according to an exemplary embodiment of the present disclosure.

FIG. 5a is a schematic diagram that schematically showing one example of a transmission path of light at the beveled surface A in FIG. 3.

FIG. 5b is a schematic diagram that schematically showing one example of a transmission path of light at the interface E in FIG. 3.

FIG. 6 is a schematic view that schematically showing a configuration of a light concentrating portion and a light transmission path of an exemplary embodiment of the present disclosure in the form of a sectional view.

FIG. 7 is a schematic view that schematically showing a configuration of a light concentrating portion and a light transmission path of another exemplary embodiment of the present disclosure in the form of a sectional view.

FIG. 8 is a schematic view that schematically showing a configuration of a light concentrating portion of still another exemplary embodiment of the present disclosure in the form of a sectional view.

FIG. 9 is a schematic view that schematically showing a configuration of an image sensor of an exemplary embodiment of the present disclosure in the form of a sectional view.

FIG. 10a to FIG. 10f are schematic views respectively showing cross sectional views of an image sensor at respective steps of an example of a method of forming an image sensor according to an exemplary embodiment of the present disclosure.

FIG. 11 is a schematic view that schematically showing a configuration of an image sensor of another exemplary embodiment of the present disclosure in the form of a sectional view.

FIG. 12a to FIG. 12h are schematic views respectively showing cross sectional views of image sensors at respective steps of an example of a method of forming an image sensor according to another exemplary embodiment of the present disclosure.

FIG. 13 is a schematic view that schematically showing a configuration of an image sensor of still another exemplary embodiment of the present disclosure in the form of a sectional view.

It should be noted that, in the embodiments described below, the same reference numerals are sometimes used to refer to the same parts or parts having the same functions, and the repeated description is omitted. In the present specification, similar reference numerals and letters are used to indicate similar items, and therefore, once an item is defined in one drawing, it is not necessary to further discuss it in the subsequent drawings.

For easy understanding, the positions, sizes, scopes, and the like shown in the drawings and the like may not represent actual positions, sizes, scopes, and the like. Therefore, the disclosed invention is not limited to the positions, sizes, and scopes disclosed in the drawings and the like.

Moreover, those skilled in the art will appreciate that the transmission path of light shown in the drawings is merely illustrative and does not constitute a limitation on any of the following: the angle and position of light incidence, the angle of light refraction, the direction of light transmission, the depth of light incident, the number of light transmission paths, and the density of light.

### DETAILED DESCRIPTION

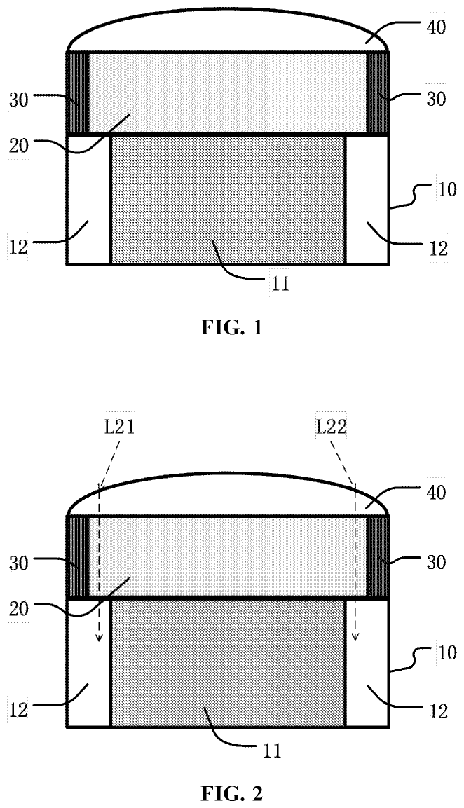

FIG. 1 shows the construction of a common image sensor. The image sensor includes a substrate 10 in which a photosensitive element 11 for sensing light, such as a photodiode or other similar device, is formed. Around the photosensitive element 11 in the substrate 10 is a pixel peripheral region 12 for isolating adjacent photosensitive elements (pixel regions) in the substrate.

The image sensor may also include a color filter layer 20 formed on the substrate 10, a micro lens 40, and an optical isolation portion 30, which may be described in more detail below. It should be noted that the image sensor of the prior art may also include other structures such as a circuit wiring layer and the like, which are not shown here.

The inventors of the present application have found through research that, in the conventional image sensor shown in FIG. 1, as shown in FIG. 2, even if the micro lens 40 has been used to concentrate the incident light in the middle of the micro lens 40, some light may still be incident on the pixel peripheral region 12 around the photosensitive element 11 in the substrate 10, see the transmission path of light shown by the broken lines L21, L22 in FIG. 2.

The light sensitivity of the image sensor relates to the amount of incident light of the photosensitive element during light irradiation. As the amount of incident light increases, the light sensitivity of the image sensor also improves. Since the pixel peripheral region 12 is not used to sense light, it is desirable to further reduce the light entering the pixel peripheral region 12 to increase the light entering the area of the photosensitive element 11, thereby further improving the light sensitivity of the image sensor.

Embodiments of the present disclosure provide an image sensor, including a light concentrating portion located in a peripheral region of a photosensitive element, and the light concentrating portion is shaped such that light entering the peripheral region of the photosensitive element is refracted to the photosensitive element region through the light concentrating portion.

It should be noted that the peripheral region of the photosensitive element means that it is formed in the peripheral region of the photosensitive element, and/or a projection area of the peripheral region (such as a projection area on the surface of the substrate in a direction perpendicular to the main surface of the substrate). The formation, for example, can be formed not only in the substrate but also in the projection area of the peripheral region on the substrate.

Exemplary embodiments of the present disclosure may be described in detail below with reference to the drawings. It should be noted that the components shown in the drawings are merely exemplary, and the drawings are simplified views to illustrate the design of the present disclosure more clearly. In actual applications, other components may be present in addition to the components shown in the figures, and the other components are not shown in order to clearly illustrate the implementation of the embodiments of the present disclosure.

The following description of the at least one exemplary embodiment is merely illustrative and is in no way intended as a limitation to the disclosure and its application or use. It should be noted that: unless specified otherwise, the relative arrangement of the components and steps, numerical expressions and numerical values set forth in the embodiments are not intended to limit the scope of the disclosure.

The techniques, methods, and devices known to one of ordinary skilled in the relevant art may not be discussed in detail, but the techniques, methods, and devices should be considered as part of the present disclosure, where appropriate.

In all of the examples shown and discussed herein, any specific values should be construed as illustrative only and not as a limitation. Therefore, other examples of the exemplary embodiments may have different values.

In the present disclosure, a reference to “one embodiment” means that a feature, structure, or characteristic described in connection with the embodiment is included in at least one embodiment of the present disclosure. Thus, appearances of the phrases “in one embodiment” in everywhere of the present disclosure may not necessarily refer to the same embodiment. Furthermore, the features, structures, or characteristics may be combined in any suitable combination and/or sub-combination in one or more embodiments.

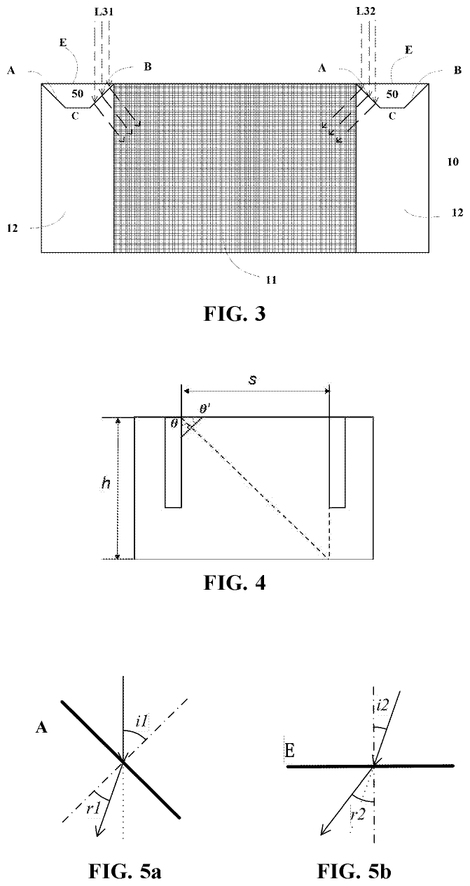

FIG. 3 schematically illustrates, in sectional view, the configuration of an image sensor of some exemplary embodiments of the present disclosure and a transmission path of light therein. Although only one photosensitive device is shown as an example in the drawings, the image sensor of one exemplary embodiment of the present disclosure may include a plurality of photosensitive devices, and generally, a plurality of photosensitive devices may form an array. Since each photosensitive device in the image sensor may adopt the same configuration, in order to avoid obscuring the present invention, only one photosensitive device is shown and described herein.

As shown in FIG. 3, the image sensor includes a substrate 10. In some embodiments, the substrate 10 may be a semiconductor substrate made of any semiconductor material suitable for a semiconductor device, such as Si, SiC, SiGe, or any combination thereof, etc., and the semiconductor material may be an intrinsic semiconductor material or doped with impurities. The substrate 10 may also be a composite substrate such as silicon-on-insulator (SOI) or silicon-on-insulator. Those skilled in the art understand that the substrate is not subject to any restrictions, but may be selected according to practical applications.

A photosensitive element 11 is formed in the substrate 10 for sensing light. As an example, the photosensitive element may be a photodiode. In the substrate 10, there is also a pixel peripheral region 12 around the photosensitive element 11, mainly for isolating adjacent photosensitive elements in the substrate. As an example, the photosensitive element 11 (photodiode region) may be achieved by different doping in the silicon substrate, and doping in the pixel peripheral region 12 of is also performed to cause electrons to flow to the photodiode region so that the electrons are collected by the circuit in the substrate (for example, a circuit formed under the photosensitive element with respect to incident light).

The image sensor further includes a first light concentrating portion 50 (also referred to hereinafter as a “first light concentrating portion”). As shown in FIG. 3, the first light concentrating portion 50 is formed in the substrate 10 in the pixel peripheral region 12, which is used to cause light incident to the peripheral region to propagate toward the photosensitive element. In the example shown in FIG. 3, the first light concentrating portion 50 is an inverted trapezoidal structure having two inclined faces A and B (the “beveled surface”) and one bottom side C, and light incident on the peripheral region and then incident on the first light concentrating portion 50 may be refracted into the corresponding photosensitive element through a beveled surface of the first light concentrating portion 50, thereby redirect unwanted light originally incident on the peripheral region (i.e., light that is not normally sensed by the photosensitive element) into the photosensitive element, increasing the amount of incident light of the photosensitive element.

In some embodiments, the first light concentrating portion 50 may coincide with a pixel peripheral region 12 of the photosensitive element 11 in a plan view parallel to the main surface of the substrate. For example, from a view along a direction perpendicular to the main surface of the substrate, the first light concentrating portion 50 may coincide with a pixel peripheral region 12 of the photosensitive element 11. Those skilled in the art will appreciate that the coincidence includes partial coincidence and complete coincidence. As an example, the cross section of the first light concentrating portion 50 may coincide with the pixel peripheral region 12 of the photosensitive element 11 in a sectional view, as exemplarily shown in FIG. A case where the first light concentrating portion 50 may be formed in the entire pixel peripheral region 12 is shown in FIG. 3. It should be noted that the first light concentrating portion 50 may also be formed only in a portion of the pixel peripheral region 12 without being formed across the entire peripheral region. It should be noted that the first light concentrating portion 50 may be partially formed in the photosensitive element region in addition to the pixel peripheral region 12. As a further example, the cross section of the first light concentrating portion 50 may at least partially coincide with the photosensitive element 11 in a plan view parallel to the main plane of the substrate 10, e.g., the cross section of the first light concentrating portion 50 may at least partially coincide with the photosensitive element 11 from a view along a direction perpendicular to the main surface of the substrate.

In some embodiments, the beveled surfaces A, B of the first light concentrating portion 50 (i.e., the side surfaces of the first light concentrating portion 50) are inclined downwards and outwards, that is, starting from a top surface of the first light concentrating portion 50 (or, in the case of the first light concentrating portion 50 does not include the top surface shown in FIG. 3, from a vertex or top side of the first light concentrating portion 50), the beveled surface extends downwards in the vertical direction of the substrate and outwards in the horizontal direction (away from the direction of corresponding photosensitive element 11). For example, the bevel A extends away from the photosensitive element (shown by the photosensitive element 11) corresponding thereto (for example, adjacent thereto), and the inclined surface B extends away from the corresponding photosensitive element (not shown in the drawing, on the right side). It may be understood by those skilled in the art that “bevel” refers to a slanted surface, and not only to a plane, for example, it may also be a slanted surface such as a conical surface. In some embodiments, the beveled surface of the first light concentrating portion 50 in the present disclosure is a straight line in a sectional view of the image sensor.

The bottom edges of the beveled surfaces A, B are located in the pixel peripheral region 12, and the top or apex of the beveled surfaces A, B may be located above the boundary of the photosensitive element 11 or above the area of the photosensitive element 11. Although the beveled surfaces A and B are shown in the peripheral region in FIG. 3, it should be understood that the beveled surfaces A and B may also be partially located in the photosensitive element region, and in particular, the beveled surfaces A and B may be partially located in the photosensitive element region above the photosensitive element which is better for the convergence of incident light to the photosensitive element.

The image sensor having the above configuration causes the light (refer to light transmission path shown by the broken lines L21, L22 in FIG. 2), which should have entered the pixel peripheral region 12 around the photosensitive element 11, to enter the first light concentrating portion 50 and then to be refracted via the beveled surface to the direction of the photosensitive element 11, the light transmission path of which is shown by the broken lines L31, L32 in FIG. 3. Therefore more light is sensed by the photosensitive element 11 to improve the light sensitivity of the image sensor.

The shape of the cross section of the first light concentrating portion 50 shown in FIG. 3 is an inverted trapezoid. In some embodiments, the cross section of the first light concentrating portion 50 may be a symmetric inverted trapezoidal arrangement, i.e., corresponding to a symmetrical trapezoid, the two beveled surface A and B being equal and forming the same angle with the bottom edge C. In some embodiments, the cross section of the first light concentrating portion 50 may also be an asymmetric inverted trapezoidal arrangement, i.e., the two beveled surface may be unequal and form a different angle from the bottom edge C.

Although the shape of the cross section of the first light concentrating portion 50 shown in FIG. 3 is an inverted trapezoid, it may be understood by those skilled in the art that the shape of the cross section of the first light concentrating portion 50 may be other polygons (for example, triangles, etc.) and graph including an arc (for example, replacing the bottom surface of the first light concentrating portion 50 shown in FIG. 3 with an arc or the like) or the like, as long as the first light concentrating portion 50 includes a beveled surface and enables the light entering the first light concentrating portion 50 to be refracted to a corresponding photosensitive element 11 through the beveled surface.

In some embodiments, the angle of the beveled surface of the cross section of the first light concentrating portion 50 requires that the angle θ′ of the bevel with respect to the substrate surface (e.g., the major surface of the substrate) should be less than the angle θ between the diagonal of the photosensitive element region and a direction perpendicular to the surface of the substrate as shown in FIG. 4. In FIG. 4, s and h indicate the size of the photosensitive element region, for example, indicating the size of the photosensitive element region in a direction parallel to the main surface of the substrate and the direction of the photosensitive element region in a direction perpendicular to the main surface of the substrate, respectively. If this relationship is not satisfied, light refracted by the beveled surface of the first light concentrating portion 50 may reach the photosensitive element region of adjacent pixels, causing crosstalk. The angle θ′ of the bevel may be achieved by adjusting the ratio of the etching gas during manufacturing of the first light concentrating portion 50. It should be noted that even if the cross section of the first light concentrating portion 50 is not trapezoidal, the angle of the beveled surface of the non-trapezoidal first light concentrating portion 50 should still satisfy the above requirements, i.e., θ′<θ.

In some embodiments, in order to achieve the effect of refracting light entering the first light concentrating portion 50 towards the photosensitive element 11, it is necessary to make the refractive index of the first light concentrating portion 50 (or at least the first light concentrating portion 50 near the bevels A, B) smaller than the refractive index of the portion of the substrate outside (below) the bevel A and B. As an example, the refractive index of the material of the first light concentrating portion 50 is smaller than the refractive index of the material of the substrate 10.

FIG. 5a is a diagram schematically showing one example of a transmission path of light at the beveled surface A in FIG. 3. Wherein, the solid line with highest weight indicates the interface of the two optical transmission media (i.e., the beveled surface A shown in FIG. 3), which is the interface between the first light concentrating portion 50 and the substrate 10, and the solid line with an arrow indicates that the transmission paths of the light in two kinds of medium, the dash dot line indicates the normal line of the interface, and the dash line indicates the extension line of the incident direction of the incident light. When the light is refracted from the beveled surface A of the first light concentrating portion 50, as shown in FIG. 5a, since the light enters the optically denser medium (e.g., higher refractive index) from optically thinner medium (e.g., lower refractive index), the refraction angle r1 is smaller than the incident angle i1, so that the transmission path of the incident light is changed to an inward deflection (i.e., the direction toward the photosensitive element 11) so that more light enters the photosensitive element 11, thereby improving the light sensitivity of the image sensor. Although FIG. 5a shows only one example of the transmission path of light at the beveled surface A, those skilled in the art will appreciate that the transmission path of light at the beveled surface B is similar to that shown in FIG. 5a.

In some embodiments, in order to make the light entering the first light concentrating portion 50 from upward of the substrate 10 further towards the beveled surface of the first light concentrating portion 50, thereby further improving the light sensitivity of the image sensor, the refractive index of the first light concentrating portion 50 (or at least the portion of the first light concentrating portion 50 being in contact with the component on the substrate 10) may be less than or equal to the refractive index of the component on the substrate 10 (or at least the portion of the component on the substrate 10 that is in contact with the first light concentrating portion 50).

FIG. 5b is a schematic diagram showing one example of a transmission path of light at the interface E in FIG. 3. Wherein, the solid line with the highest weight indicates the interface of the two optical transmission media (i.e., the interface E shown in FIG. 3), which is the interface between the first light concentrating portion 50 and other components formed on the substrate 10. The solid line with an arrow indicates the transmission paths of light in the two transmission media, the dash dot line indicates the normal line, and the dash line indicates the extension line of the transmission direction of the incident light. If the refractive index of the first light concentrating portion 50 is equal to the refractive index of the component on the substrate 10 (or at least the portion of the substrate 10 that is in contact with the first light concentrating portion 50), the light enters the first light concentrating portion 50 from upwards of the substrate 10. At this time, the light transmission path does not change, that is, as shown in FIG. 3, the light can still be incident on the beveled surface of the first light concentrating portion 50. If the refractive index of the first light concentrating portion 50 is smaller than the refractive index of the component on the substrate 10 (or at least the portion of the component on the substrate 10 that is in contact with the first light concentrating portion 50), as shown in FIG. 5b, when the light entering the first light concentrating portion 50 from upward of substrate 10, since the light entering optically thinner medium from the optically dense medium, the refraction angle r2 is greater than the incident angle i2, so that the transmission path of the incident light is changed to be inwardly deflected, for example, corresponding to the bottom surface C, portion of the incident light will refract toward the beveled surface, thereby further improving the light sensitivity of the image sensor.

In some embodiments, as shown in FIG. 3, the beveled surface A, B of the first light concentrating portion 50 may be in direct contact with the substrate 10 as a contact surface of the first light concentrating portion 50 with the substrate 10, that is, There is no other optical transmission medium between the beveled surface of the first light concentrating portion 50 and the substrate 10. So that the light refracted by the first light concentrating portion 50 passes directly through the interface A or B of the first light concentrating portion 50 and the substrate 10, and no longer passes through the other two optical transmission media, therefore prevents the light that has been refracted by the first light concentrating portion 50 toward the direction of the photosensitive element 11 from undergoing excessive refraction or reflection to change the transmission path of the light.

In some embodiments, the surface of the first light concentrating portion 50, such as a bevel surface and/or a bottom surface, may be further formed with an anti-reflective coating/anti-reflection layer such that more light may enter the first light concentrating portion 50 rather than being reflected out by the surface which helps to allow more light to enter the photosensitive element 11.

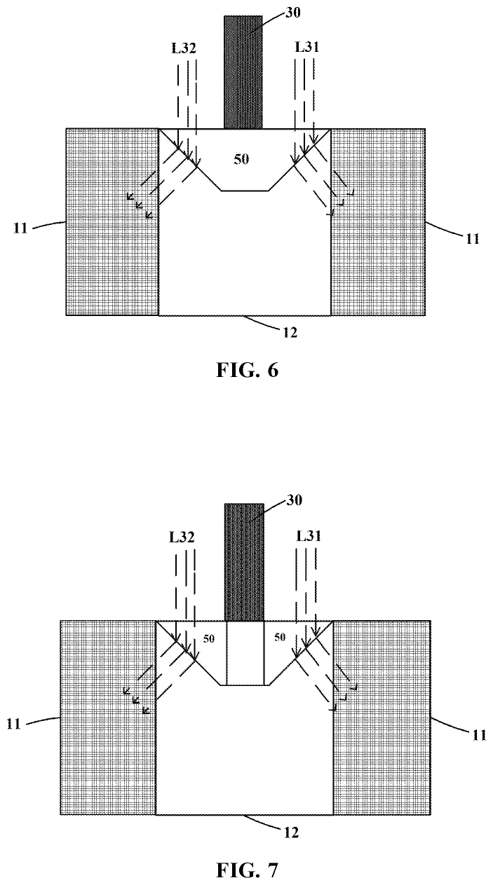

Furthermore, it should be noted that only one example of a photosensitive element is shown in FIG. 3, and in practice, there may be a plurality of adjacent photosensitive elements arranged in parallel, i.e., there may be a matrix of photosensitive elements arranged in a single substrate. In some embodiments, a first light concentrating portion 50 may be shared by two adjacent photosensitive elements. That is, light incident into the same first light concentrating portion 50 may be refracted to different photosensitive elements through the two opposite beveled surfaces A and B, respectively, that is, the two photosensitive elements respectively corresponding to the beveled surfaces A and B. FIG. 6 shows that light incident on the first light concentrating portion 50 is refracted to the corresponding two photosensitive elements via the two beveled surfaces A and B, respectively. Herein, the photosensitive element corresponding to the beveled surfaces means (for example, in a direction parallel to the surface of the substrate or in a direction perpendicular to the surface of the substrate) the photosensitive element adjacent to the beveled surface of the light concentrating portion, and outside/below the beveled surface of light concentrating portion.

In some other embodiments, different light concentrating portions 50 may be respectively provided to two adjacent photosensitive elements. That is, in a peripheral region of the two adjacent photosensitive elements, there may be arranged a plurality of first light concentrating portions 50 for the two adjacent photosensitive elements. Light beams incident into the peripheral region may be refracted into the photosensitive elements respectively via the light concentrating portions, i.e., each of the a plurality of first light concentrating portions 50 serves to exclusively refract lights to a corresponding photosensitive element. FIG. 7 illustrates an example of such design. Two light concentrating portions 50 are formed in the peripheral region, each of the two first light concentrating portions 50 may include beveled surface(s) facing only towards the corresponding photosensitive element, so that each of which is used for the corresponding photosensitive elements. It should be noted that the two light concentrating portions may also be adjacent to each other.

In this case, it should be noted that the first light concentrating portion 50 may be an irregular inverted trapezoid, such as a right-angled trapezoid, or any other shape, such as a right-angled triangle or the like, as long as the side of the corresponding photosensitive element is beveled and able to refract light to the photosensitive element.

It should be noted that in the case where the light concentrating portion is formed to be shared by the adjacent photosensitive elements, the optical separating portion is generally formed above the central of the light concentrating portion, for example, in the case where the light concentrating portion is an inverted trapezoid, the optical separating portion may be formed at the corresponding position of the short side of the inverted trapezoid. In the case where the light concentrating portions are formed as separate light concentrating portions for the respective photosensitive elements, the optical separating portion may be formed at a position between the two light concentrating portions.

With the above configuration of the first light concentrating portion 50, the image sensor of the present disclosure may further increase the amount of light incident on the photosensitive element region without substantially affecting the configuration of the photosensitive element region and above, thereby improving the light sensitivity of the image sensor. That is to say, the light concentrating portion of the present disclosure may be incorporated into the configuration of any existing image sensor, and the configuration of the components above the photosensitive element of the image sensor is not affected, and the transmittance of incident light from above is basically not affected. For example, the shape and performance of other components formed on the substrate in the image sensor, such as color filters, micro lenses, anti-reflection layers, and the like, are not affected.

Moreover, the first light concentrating portion 50 is formed in the substrate, and this manner of formation benefits from the processing. For example, a smooth transmissive surface is easily formed by oxidative etching on a silicon substrate, whereby a light concentrating portion is easily formed in the substrate.

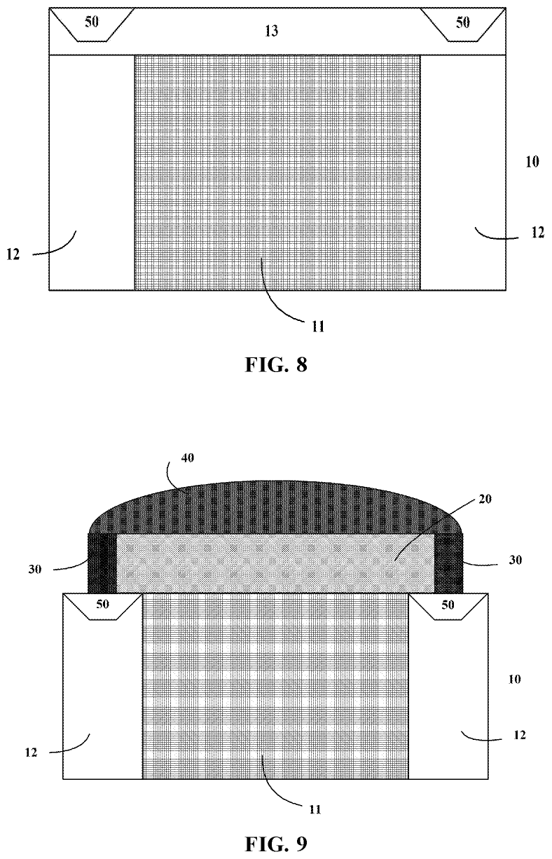

Although FIG. 3 shows that the first light concentrating portion 50 is formed in the substrate, it should be noted that the first light concentrating portion 50 may be formed in other manners as long as the first light concentrating portion 50 enables the light entering the pixel peripheral region 12 around the photosensitive element 11 to be refracted in the direction of the photosensitive element 11 by the first light concentrating portion 50. For example, in some embodiments, the first light concentrating portion 50 may be formed in a projection region (e.g., a region above the peripheral region) over the peripheral region on the substrate 10, such as in an enhanced transmission layer in the overlying pixel region (photosensitive element region) on the substrate. It may be formed even in the color filter layer covering the pixel region (photosensitive element region) as shown in FIG. 8. It should be noted that the first light concentrating portion 50 may also be partially located above the photosensitive element region, so that more light is transmitted to the photosensitive element.

As shown in FIG. 8, the beveled surface of the first light concentrating portion 50, that is, the interface between the first light concentrating portion 50 and another member 13 on the image sensor (for example, the enhanced transmission layer, the color filter layer, etc.), may cause the light incident to the first light concentrating portion 50 to be transmitted to the photosensitive element via the interface. The light transmission at this interface may be as described above in connection with FIG. 5a. That is, the refractive index of the first light concentrating portion 50 may be smaller than the that of another element in contact with the first light concentrating portion 50, so that the incident angle of the light incident on the beveled surface of the first light concentrating portion 50 is greater than the angle of refraction thereof, so that the part of light that should have been transmitted to the peripheral region without being captured by the photosensitive elements is refracted to the photosensitive elements, thereby further increasing the amount of light entering the photosensitive element, improving the light sensitivity of the image sensor. In some embodiments, in addition to being in the peripheral region, the beveled surface of the first light concentrating portion 50 may be at least partially over the area of a photosensitive element to aid further concentrating incident light to the photosensitive element. It should be noted that although FIG. 8 shows that the first light concentrating portion 50 is only located in the component 13 without being in contact with the substrate, it should be noted that the first light concentrating portion 50 may also be in direct contact with the substrate. In a further example, even the first light concentrating portion 50 may extend all the way down into the area 12 of the pixel, i.e. the light concentrating portion is located in both the component 13 and the peripheral region.

In some embodiments, a color filter layer 20 may be formed on the substrate 10 to allow light of a specific wavelength range to pass through and enter the photosensitive element 11, as shown in FIG. 9. The color filter layer 20 may be made of a pigment or dye material that only allows light of some wavelengths to pass. In some embodiments, red, blue, or green light may be allowed to pass. In other embodiments, cyan, yellow, or deep red may be allowed to pass. However, these are only exemplary colors that the color filter layer can filter, and those skilled in the art will appreciate that the color filter layer in the present disclosure may also allow light of other colors to pass. Further, the color filter layer may be made of other materials such as a light-reflecting material capable of reflecting light of a specific wavelength or the like.

In some embodiments, as shown in FIG. 9, the image sensor may further include an optical isolation portion 30. The optical isolation portion 30 is located on the substrate 10 and defines the boundary of each photosensitive device of the image sensor to form an optical shield between each photosensitive device of the image sensor to reduce interference of incident light to adjacent photosensitive devices. In some embodiments, the optical isolation portion 30 is formed from a reflective material. In some embodiments, the optical isolation portion 30 may be formed from a metallic material, such as tungsten or copper. The optical isolation portion 30 reflects the light reaching its surface (particularly the side surface of the optical isolation portion 30) inwardly, enabling more light to reach the photosensitive element 11. In addition, for those light that is reflected by the optical isolation portion 30 and still enters the peripheral region and cannot reach the region of the photosensitive element 11, the first light concentrating portion 50 causes their transmission path to be further deflected inwardly, thereby further increasing the possibility of the light reaching photosensitive element 11. It is foreseeable that the first light concentrating portion 50 can cooperate with the optical isolation portion 30 to enable more light to enter the photosensitive element 11, thereby further improving the light sensitivity of the image sensor.

In some embodiments, the optical isolation portion 30 may be a metal grid formed of a metallic material. In some embodiments, the metal grid may be formed by patterning the deposited metal layer. In other embodiments, patterning the deposited or grown non-metal layer (e.g., a layer of semiconductor material or dielectric material) and then form a metal grid by forming a metal film on the side surface (at least side surface, may also include a top surface) of the patterned non-metal layer.

In some embodiments, as shown in FIG. 9, the image sensor may further include a micro lens 40 above the photosensitive element 11. The micro lens 40 is used to converge light incident thereon such that more light reaches the region of the photosensitive element 11. Even if there is light that the micro lens 40 cannot effectively converge, such as light incident on the peripheral region, the transmission path of this portion of the light is further deflected inwardly to the photosensitive element 11 when the portion of the light is incident on the first light concentrating portion 50, thereby further increasing the possibility that the light can reach the photosensitive member 11. It is foreseeable that the first light concentrating portion 50 can cooperate with the micro lens 40 to enable more light to enter the photosensitive element 11, thereby further improving the light sensitivity of the image sensor. Although the micro lens 40 is formed on the color filter layer and the optical isolation portion in the photosensitive device of the image sensor shown in FIG. 9, those skilled in the art may understand that under the situation that the image sensor does not include the color filter layer or the optical isolation portion, the micro lens 40 may be formed directly on the substrate 10 to cover the substrate and the light concentrating portion.

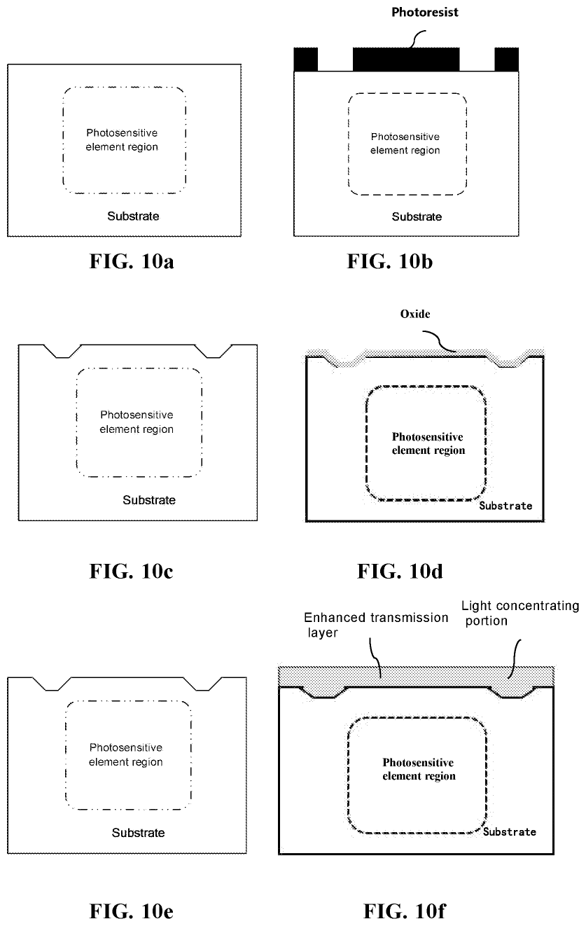

In some embodiments, an image sensor in accordance with some embodiments of the present disclosure may be formed in the following method. This may be specifically described below in accordance with FIG. 10a to FIG. 10f. Those skilled in the art will appreciate that the steps in the following description are merely illustrative, and one or more steps or processes may be omitted or added depending on the actual application.

As shown in FIG. 10a, a substrate 10 including a photosensitive element 11 is provided. The configuration and type of the photosensitive element 11 are not limited, and for example, the photosensitive element 11 may be a PN junction type photosensitive element. A peripheral region may also be formed around the photosensitive element in the substrate, and a device layer may be formed above or below the photosensitive element, which is not shown in the drawings for the sake of clarity.

As shown in FIG. 10b, a photoresist is coated on the substrate 10 and then exposed to form an opening in the photoresist at a position where the light concentrating portion is intended to be formed. The material of the photoresist, as well as the coating and exposure of the photoresist, may be achieved using materials known in the art as well as known techniques, and will not be described in detail herein.

As shown in FIG. 10c, the substrate is etched and the photoresist is removed to form a recess. Substrate etching may be accomplished using techniques known in the art and will not be described in detail herein. The recess may have the shape of a desired light concentrating portion, such as an inverted trapezoidal shape as described herein. The angle of the beveled surface of the light concentrating portion should also be such that the angle between the beveled surface and the surface of the substrate is smaller than the angle between the diagonal of the photosensitive element region and a direction perpendicular to the surface of the substrate, as described herein, and the angle of the beveled surface may be adjusted by adjusting the etching process parameters, for example, by adjusting the ratio of the etching gas.

Photoresist removal may be accomplished using techniques known in the art, such as ashing methods, which will not be described in detail herein.

As shown in FIG. 10d, the etched silicon substrate is oxidized to form an oxide on the surface of the substrate. As an example, In Situ Steam Generation (ISSG) may be performed to form silicon oxide on the surface of the silicon substrate. ISSG is a process for feeding H₂ and O₂ into a furnace tube at a high temperature to oxidize the surface of silicon to improve the flatness of the silicon surface. Other oxidation methods may also be considered for the oxidation of the substrate surface.

As shown in FIG. 10e, the surface of the silicon substrate after oxidation is etched to remove oxides. As an example, wet etching (e.g., using hydrofluoric acid) may be performed to remove silicon oxide on surface to obtain a smooth bevel.

As shown in FIG. 10f, a material is deposited on the treated silicon substrate, and then the deposited material is flattened and polished to obtain a light concentrating portion. Further, the refractive index of the material should be smaller than that of the substrate material, so that light may be turned to the photosensitive element region via the beveled surface of the light concentrating portion when incident into the light concentrating portion.

The material may be deposited by, for example, chemical vapor deposition (CVD), physical vapor deposition (PVD), atomic layer deposition (ALD), or other suitable technique, and the material is transparent to visible light. For example, the material may be silicon oxide, hi-k material or other dielectric material that is transparent to visible light. As an example, chemical mechanical flattening may be performed for polishing.

As an example, when depositing a material, in addition to the recess, a certain thickness of the material may be deposited on the substrate as other structural layers of the image sensor formed integrally with the light concentrating portion (depending on the role of the deposited material), as shown in FIG. 10f. For example, the material may be used for enhanced transmission layer, so that the light concentrating portion may be integrally formed with the enhanced transmission layer.

In some embodiments, only the light concentrating portion may be formed by the above process, and after the light concentrating portion is formed, a enhanced transmission layer or other structural layer may be formed by other processes (e.g., deposition, etc.), the material of which may be different to the light concentrating portion.

It should be noted that the anti-reflection layer may be first formed in the light concentrating portion before the light concentrating portion is filled with the material. The material of the anti-reflective layer is a dielectric material such as silicon oxide, hafnium oxide, silicon nitride, aluminum oxide or hafnium oxide or a combination of several layers of the above materials. The material of the anti-reflective layer may be the same as or different from the filling material of the light concentrating portion.

In other embodiments, the light concentrating portion may be formed on the substrate. As an example, an enhanced transmission film or other structural layer may be formed first on the surface of the substrate by deposition, and then the above-described steps of FIG. 10b to FIG. 10f are performed on the enhanced transmission film or other structural layer to form the light concentrating portion in the enhanced transmission film.

Further, after the above-described structure is formed, the color filter layer, light shielding portion, and micro lens may be further formed on the above structure. These components may be formed according to any of the processes well known in the art and will not be described in detail herein.

Image sensors typically include a front-illuminated (FSI) image sensor and a back-illuminated (BSI) image sensor. In the front-illuminated image sensor configuration, in the incident direction of light, micro-lens, color filter, wiring layers, and photodiodes are sequentially arranged from top to bottom, and the light is incident from the micro lens side to the photosensitive element. In contrast, in the back-illuminated image sensor configuration, the positions of the photosensitive element and the circuit layer are reversed, and in the incident direction of the light, micro-lens, color filter, photodiodes and wiring layers are sequentially arranged from top to bottom. In a back-illuminated image sensor, light is incident from the back side, and wiring layers (devices and circuits) are located under the substrate with respect to the photodiode, distributed on the front side, so incident light will first be incident on the photodiode, thereby the interference in the circuit layer is reduced, the amount of incident light is increased, and the light sensitivity of the image sensor is improved. Moreover, the BSI image sensor device provides a high fill factor and reduces destructive interference compared to the FSI.

In the implementation of a back-illuminated image sensor, in order to reduce the crosstalk of light between pixels, the researchers produced back trench isolation on a silicon substrate. Specifically, a trench isolation region is inserted in the back surface of the device layer between adjacent pixels. Depending on the depth of the trench, it may be divided into shallow trench isolation and deep trench isolation. Deep trench isolation may better suppress crosstalk between pixel regions compared to shallow trench isolation. However, the introduction of deep trenches takes up a certain area of the pixel area, which reduces the sensitivity of the image sensor. Moreover, in order to reduce the dark current, the deep trench edge usually undergoes an inverted P+ doping, which results in a decrease in full well capacity (FWC).

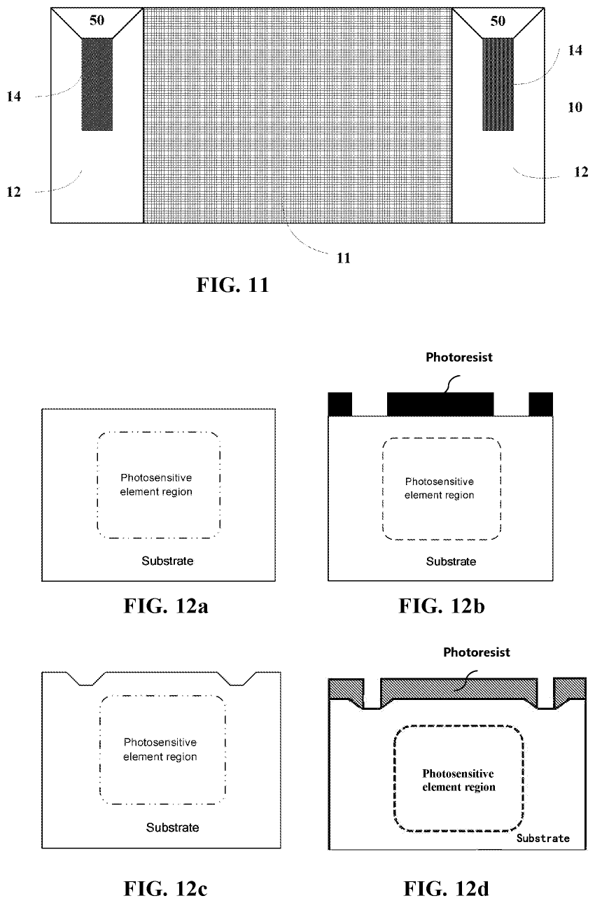

In some embodiments of the present application, the technical solution of the light concentrating portion in the present application may be implemented in combination with deep trench isolation to form a composite deep trench isolation structure. While reducing the crosstalk of light between pixels, it is also possible to cause more light to be incident into the pixels, thereby increasing the sensitivity of the image sensor. FIG. 11 illustrates a configuration of an image sensor in which a first light concentrating portion 50 and a deep trench isolation portion 14 form a composite deep trench isolation structure, in accordance with some embodiments of the present disclosure.

The produce process of a composite deep trench isolation structure for a back-illuminated image sensor in accordance with some embodiments of the present disclosure may be described below with reference to the accompanying drawings.

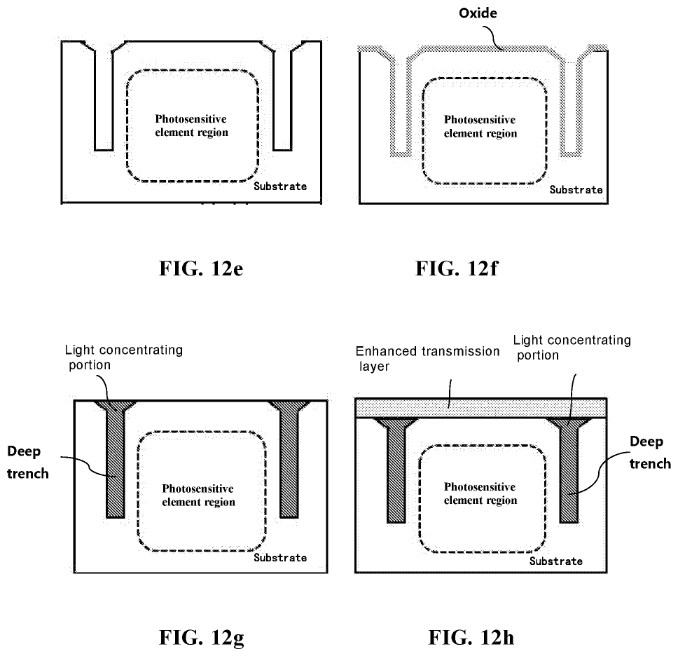

The process showing in FIG. 12a to FIG. 12c is substantially similar to the process described above with reference to FIG. 9a to FIG. 9c, the detailed process of which will not be described in detail. In particular, for a back-illuminated image sensor, a photosensitive element region may be formed in a silicon substrate and a device layer is formed over the photosensitive element region, and then the back side of the substrate is faced upward after the device layer is completed. The above operation is then performed on the back side of the substrate.

As shown in FIG. 12d, a photoresist is further coated on the surface of the silicon substrate on which the recess is formed, and then lithography is performed to form an opening of the photoresist on the recess, the opening will serve as an opening for forming the back deep trench.

As shown in FIG. 12e, the silicon substrate is etched to form a deep trench on the back side, and then the photoresist is removed. Removing the photoresist may be carried out by any method known in the art, such as ashing as described above.

Oxidation is carried out to form an oxide as shown in FIG. 12f, which may be carried out in the same manner as in FIG. 9d, such as by ISSG.

As shown in FIG. 12g, the surface of the silicon substrate after oxidation is etched to remove oxides as shown in FIG. 9e. As an example, wet etching (e.g., using hydrofluoric acid) may be performed to remove surface silicon oxide to obtain a smooth bevel.

A material is then deposited on the treated silicon substrate, and then the deposited material is flattened and polished to obtain a light concentrating portion and a deep trench isolation portion. Further, the refractive index of the material should be smaller than that of the substrate material, so that light may be turned to the photosensitive element region via the beveled surface of the light concentrating portion when incident into the light concentrating portion. The manner of deposition and material type of the material may be as described herein and will not be described in detail herein.

It should be noted that the anti-reflective layer may first be formed in the light concentrating portion before the light concentrating portion is filled with the material, as described herein.

Then, as shown in FIG. 12h, other structural layers of the image sensor may be formed on the silicon substrate. The material of the other structural layer may be the same as or different from the material of the light concentrating portion.

Further, after the above-described configuration is formed, the color filter layer, the light shielding portion, and the micro lens may be further formed on the above structure. These components may be formed according to any of the processes well known in the art and will not be described in detail herein.

In some embodiments of the present disclosure, in addition to forming the first light concentrating portion 50 on the substrate 10 as described above, a second light concentrating portion may be formed on the substrate such that more light further enters the photosensitive element 11, thereby making the light sensitivity of the image sensor further improved. The implementation of this form of second light concentrating portion may be described in detail below.

In some embodiments, the second light concentrating portion is formed refer to a corresponding photosensitive element and at least partially coincides with the photosensitive element and the associated first light concentrating portion. In some embodiments, the second light concentrating portion may coincide with the photosensitive element and the first light concentrating portion in a plan view parallel to the main surface of the substrate, for example, from a view along a direction perpendicular to the surface of the substrate, it at least partially coincides with the photosensitive element and the first light concentrating portion. Coincidence includes partial coincidence and complete coincidence.

In some embodiments, the second light concentrating portion includes a beveled surface configured to enable light incident to the second light concentrating portion to be refracted by the beveled surface to achieve aggregation of light. The beveled surface of the second light concentrating portion may coincide with the first light concentrating portion located in the peripheral region such that light incident on the beveled surface may be refracted toward the direction of the first light concentrating portion. Further, the beveled surface of the second light concentrating portion may coincide with the photosensitive element, so that light incident on the beveled surface may be refracted toward the direction of the photosensitive element 11. It should be noted that the beveled surface of the second light concentrating portion may not coincide with the photosensitive element.

The second light concentrating portion may or may not be in contact with the substrate and the first light concentrating portion. For example, a second light concentrating portion may be formed on the substrate 10, in contact with the substrate 10, and partially in contact with the first light concentrating portion. It should be noted that in other examples, the second light concentrating portion may be formed over the photosensitive element, such as other structural layers of the image sensor, such as an enhanced transmission layer, etc., between the substrate and the second light concentrating portion.

By setting the second light concentrating portion, the light incident to the peripheral region is first refracted by the beveled surface of the second light concentrating portion, thereby more light being incident on the first light concentrating portion formed in the substrate, especially incident on the first beveled surface of the light concentrating portion. Light incident on the beveled surface of the first light concentrating portion is further refracted into the photosensitive element via the beveled surface. Thereby, such a combined light concentrating portion achieves that the amount of light incident into the photosensitive element may be further increased, which in turn further improves the light sensitivity of the image sensor.

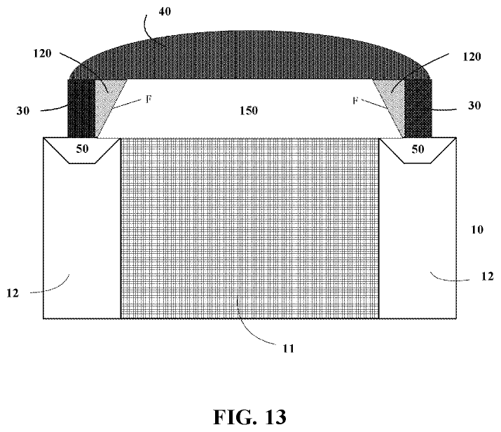

FIG. 13 illustrates a configuration of an image sensor including a second light concentrating portion 150 according to an embodiment of the present disclosure. The beveled surface F of the second light concentrating portion 150 (i.e., a side surface of the second light concentrating portion 150, which is beveled) is beveled downwards and outwards, that is, from the top surface of the second light concentrating portion 150 (or, in the case where the second light concentrating portion 150 does not include a top surface as shown in FIG. 13, from the apex or top side of the second light concentrating portion 150) extending downwards in the vertical direction and outward in the horizontal direction (i.e., away from the photosensitive element 11). The bottom edge of the bevel is located within the pixel peripheral region 12, and the top side or vertex of the bevel is above the boundary of the photosensitive element 11 or above the area of the photosensitive element 11. It may be understood by those skilled in the art that “bevel” refers to a slanted surface, and not only to a plane, for example, it may also be a slanted surface such as a conical surface. In some embodiments, the beveled surface F of the second light concentrating portion 150 in the present disclosure is a straight line in a sectional view of the image sensor.

Although the shape of the cross section of the second light concentrating portion 150 shown in FIG. 13 is trapezoidal, those skilled in the art may understand that the shape of the cross section of the second light concentrating portion 150 may be other polygons (for example, triangles, etc.) and graph including an arc (for example, the upper surface of the second light concentrating portion 150 shown in FIG. 13 is replaced by an arc or the like) or the like, as long as the second light concentrating portion 150 includes a beveled surface F that enables the light entering the second light concentrating portion 150 via the beveled surface F to be refracted to the first light concentrating portion in the peripheral region.

As described in the disclosure for the light transmission path at the beveled surface, in order to achieve the effect of refracting the light entering the second light concentrating portion 150 via the beveled surface F towards the photosensitive element 11 and the beveled surface A, B of the first light concentrating portion 50, it is necessary to make the refractive index of the second light concentrating portion 150 (or at least the portion of the second light concentrating portion 150 that is close to the beveled surface F) greater than that of the portion of the beveled surface that is in contact therewith. As such, when light is refracted from the beveled surface into the second light concentrating portion 150, the angle of refraction is smaller than the angle of incidence, so that the transmission path of the incident light is changed to be inward (i.e., toward the photosensitive element 11 and the first light concentrating portion), thereby causing more light entered the photosensitive element 11 and the beveled surface A, B of the first light concentrating portion, thereby improving the light sensitivity of the image sensor. The transmission path of light at the beveled surface F of the second light concentrating portion 150 is similar to that described herein with reference to FIG. 5a and will not be described in detail herein.

The light transmission path at the interface of the second light concentrating portion 150 and the first light concentrating portion 50 is similar to the light transmission path at the interface E as shown in FIG. 5b as described above. In some embodiments, the refractive index of the second light concentrating portion 150 (or at least the portion of the second light concentrating portion 150 that is in contact with the first light concentrating portion 50) maybe greater than or equal to that of the first light concentrating portion 50 (or at least a portion of the first light concentrating portion 50 that is in contact with the second light concentrating portion 150), such that when light is incident to the interface, the angle of refraction is greater than the angle of incidence, thereby changing the transmission path of the incident light to be inwardly (That is, towards the photosensitive element 11 and the first light concentrating portion 50) so that more light enters the beveled surface of the photosensitive element 11 and the first light concentrating portion, thereby improving the light sensitivity of the image sensor.

The cross section of the second light concentrating portion 150 may include any other shape as long as the cross section of the second light concentrating portion 150 include a beveled surface and the beveled surface causes the light incident to the peripheral region to be reflected to the photosensitive element and the beveled surface of the first light concentrating portion. For example, the cross section of the second light concentrating portion may be an inverted trapezoidal shape opposite to the trapezoidal shape of the second light concentrating portion shown in the previous figure.

In some embodiments, the surface of the second light concentrating portion 150 may be formed with an anti-reflective layer such that more light may enter the second light concentrating portion 150 instead of being reflected by its surface, thereby further improving the light sensitivity of the image sensor.

In some embodiments, the image sensor may include a filling layer 120 in addition to the substrate 10 and the second light concentrating portion 150 described in the above embodiments, as shown in FIG. 13. The filling layer 120 is located above the first light concentrating portion 50 and covers the surface of the second light concentrating portion 150. As described above, the refractive index of the second light concentrating portion 150 (or at least the portion of the second light concentrating portion 150 near the beveled surface) is larger than that of the filling layer 120 (or at least the portion of the filling layer 120 that is in contact with the second light concentrating portion 150). As such, when light is refracted from the beveled surface of the second light concentrating portion 150 into the second light concentrating portion 150, the angle of refraction is smaller than the angle of incidence, so that the transmission path of the incident light is changed to be inwardly deflected, so that more light may enter the photosensitive element 11, thereby improving the light sensitivity of the image sensor.

In some embodiments, the filling layer 120 may include a color filter function to allow light of a specific wavelength range to pass through and enter the photosensitive element 11. The filling layer 120 including a color filter function may be made of a pigment or dye material, as described above for the color filter layer, and will not be described in detail herein.

In some embodiments, the outer edge of the second light concentrating portion 150 is in contact with the optical isolation portion 30, as shown in FIG. 13. In this way, it is possible to prevent light that is to be incident on the pixel peripheral region 12 from entering the substrate 10 without passing through the second light concentrating portion 150, thereby increasing the possibility that light may reach the photosensitive element 11, so that more light may be incident on the photosensitive element 11. In some embodiments, the height of the second light concentrating portion 150 may be less than or equal to the height of the optical isolation portion 30, as shown in FIG. 13, to ensure an optical shielding effect of the optical isolation portion 30.

In some embodiments, the image sensor may further include a micro lens 40, as shown in FIG. 13.

In some embodiments, deep trench isolations may also be formed further in the image sensor shown in FIG. 13, which is not shown here for the sake of clarity.

The formation of an image sensor including a combination of the first and second light concentrating portions may be briefly described below.

First, the configuration of the image sensor including the first light concentrating portion may be achieved as described above with reference to the accompanying drawings, as shown in FIG. 10a-f or 12a-12h.

An optical isolation portion is then formed at the boundary of each photosensitive device in the image sensor on the substrate. The optical isolation portion may be formed in a variety of ways and will not be described in detail herein.

Then, a material layer is formed on the substrate 10 between the optical isolation portions, the material of the layer is same as that of the second light concentrating portion. The material layer may be formed by a variety of techniques in the art, such as deposition techniques, as well as other suitable techniques, and will not be described in detail herein. Furthermore, in order to avoid or mitigate the adverse effects on the already formed optical isolation portion or other portions of the image sensor when forming the material layer, the process temperature is controlled to be less than or equal to 700 degrees Celsius in the process of forming the material layer.

Then, the material layer is patterned to form the second light concentrating portion 150, and the height of the formed second light concentrating portion 150 is made smaller than or equal to the height of the optical isolation portion. Patterning may be accomplished by a variety of techniques known in the art, such as etching, etc., and will not be described in detail herein.

Then, a filling layer is formed on the second light concentrating portion 150, and the filling layer covers the surface of the second light concentrating portion 150. Finally, a micro lens is formed for the photosensitive device of the image sensor. The formation of the fill layer and micro lenses may be accomplished by a variety of techniques known in the art and will not be described in detail herein.

Although the configuration of the image sensor of the pixel region is schematically illustrated in the form of a sectional view only in the drawings of the present disclosure, those skilled in the art may obtain the overall configuration and forming method of the image sensor according to the present disclosure and based on the contents described in the present disclosure.

The word “A or B” in the specification and claims includes “A and B” and “A or B”, and does not exclusively include only “A” or only “B” unless specifically stated otherwise.

The words “before”, “after”, “top”, “bottom”, “above”, “below”, etc. in the specification and claims, if present, are used for descriptive purposes, but not necessarily for describing the unchanged relative position. It may be understood that the terms so used are interchangeable, where appropriate, such that the embodiments of the present disclosure described herein are, for example, able to operate in orientations than those described or otherwise described herein.

As used herein, the word “exemplary” means “serving as an example, instance, or illustration” rather than as a “model” to be precisely copied. Any implementations exemplarily described herein are not necessarily to be construed as preferred or advantageous over other implementations. Furthermore, the present disclosure is not limited by any of the stated or implied theory presented in the above technical field, the background art, the invention or the specific embodiments.

As used herein, the word “substantially” is intended to include any minor variation resulting from a design or manufacturing defect, a device or component tolerance, environmental influence, and/or other factors. The word “substantially” also allows for differences from perfect or ideal situations caused by parasitic effects, noise, and other practical considerations that may exist in actual implementations.

The above description may indicate elements or nodes or features that are “connected” or “coupled” together. As used herein, “connected” means that one element/node/feature is electrically, mechanically, logically, or otherwise directly connected to another element/node/feature (or Direct communication), unless otherwise explicitly stated. Similarly, “coupled” means that one element/node/feature may be mechanically, electrically, logically, or otherwise linked in a direct or indirect manner to another element/node/feature in order to allow interactions, unless otherwise explicitly stated, even if these two features may not be directly connected. That is, “coupled” is intended to include both direct and indirect connection of elements or other features, including the connection of one or more intermediate elements.

In addition, certain terminology may be used in the following description for the purpose of reference only, and thus is not intended to be limiting. For example, the words “first”, “second”, and other such numerical terms referring to the structure or element do not imply the order.

It is also should be understood that the words “including” or “comprising”, as used herein, indicate the presence of features, integers, steps, operations, units and/or components, but do not preclude the presence or attachment of one or more other features, integers, steps, operations, units, components and/or their combinations.

In the present disclosure, the term “providing” is used broadly to encompass all manner of obtaining an object, and thus “providing an object” includes but is not limited to “purchase”, “preparation/manufacturing”, “arrangement/setting”, “installation/assembly”, and/or “order” objects, etc.

Those skilled in the art will appreciate that the boundaries between the above operations are merely illustrative. Multiple operations may be combined into a single operation, a single operation may be distributed among additional operations, and operations may be performed at least partially overlapping in time. Moreover, alternative embodiments may include multiple instances of a particular operation, and the operational sequence may be varied in other various embodiments. However, other modifications, changes, and replacements are possible. Accordingly, the specification and drawings are to be regarded as illustrative rather than restrictive.

Although some specific embodiments of the present disclosure have been described in detail by way of example, it should be understood that the above examples are for illustrative purposes only and are not intended to limit the scope of the disclosure. The various embodiments disclosed herein may be combined in any combination without departing from the spirit and scope of the disclosure. It may be understood by those skilled in the art that various modifications may be made to the embodiments without departing from the scope and spirit of the disclosure. The scope of the disclosure is defined by the claims.

What is claimed is:

1. An image sensor, comprising:
a substrate including a photosensitive element region; and
a first light concentrating portion in a peripheral region of the photosensitive element region,
wherein the first light concentrating portion is formed such that light entering the peripheral region is refracted towards the photosensitive element region through the first light concentrating portion.

2. The image sensor as claimed in claim 1 wherein:
the first light concentrating portion is formed in the substrate, and
an refractive index of the first light concentrating portion is smaller than a refractive index of a portion of the substrate in contact with the first light concentrating portion.

3. The image sensor as claimed in claim 1, wherein the first light concentrating portion includes a first beveled surface such that light incident in the first beveled surface is refracted towards the photosensitive element region.

4. The image sensor as claimed in claim 3, wherein an angle between the first beveled surface and a surface of the substrate is smaller than an angle between a diagonal of the photosensitive element region and a direction perpendicular to the surface of the substrate.

5. The image sensor as claimed in claim 3, wherein
the first light concentrating portion and the peripheral region at least partially coincide with each other from a view along a direction perpendicular to a main surface of the substrate, and
the first beveled surface of the first light concentrating portion is inclined downwards and outwards, a bottom edge of the first beveled surface is located in the peripheral region, and a top edge or a vertex of the first beveled surface is at a boundary of the photosensitive element region, above the boundary of the photosensitive element region, of above the photosensitive element region.

6. The image sensor as claimed in claim 1, further comprising a color filter layer above the photosensitive element region and at least partially covering the photosensitive element region and the first light concentrating portion,
wherein a refractive index of the color filter layer is greater than a refractive index of the first light concentrating portion.

7. The image sensor as claimed in claim 1, further comprising:
a second light concentrating portion, located at least partially above the photosensitive element region, including a second beveled surface,
wherein the beveled surface is configured such that light incident in the second beveled surface is refracted towards the photosensitive element region.

8. The image sensor as claimed in claim 7 wherein:
the second light concentrating portion at least partially coincide with the photosensitive element region and the peripheral region from a view along a direction perpendicular to a main surface of the substrate, and
wherein the second beveled surface of the second light concentrating portion at least partially covers the peripheral region in a projection perpendicular to a direction of the main surface.

9. The image sensor as claimed in claim 7, wherein the second light concentrating portion is formed on the substrate, and a refractive index of the second light concentrating portion is greater than or equal to a refractive index of the portion of the substrate that is in contact with the second light concentrating portion.

10. The image sensor as claimed in claim 7, further comprising a filling layer including a color filter function formed on the second light concentrating portion, the filling layer covering the surface of the second light concentrating portion,
wherein, a refractive index of the filling layer is smaller than a refractive index of the second light concentrating portion.

11. A method of forming an image sensor, comprising:
providing a substrate including a photosensitive element region; and
forming a first light concentrating portion in a peripheral region of the photosensitive element region,
wherein the first light concentrating portion is formed such that light entering the peripheral region of the photosensitive element is refracted towards the photosensitive element region.

12. The method as claimed in claim 11, wherein
the first light concentrating portion is formed in the substrate, and a refractive index of the first light concentrating portion is smaller than a refractive index of a portion of the substrate that is in contact with the first light concentrating portion.

13. The method as claimed in claim 11, wherein the first light concentrating portion is formed with a first beveled surface such that the light entering the peripheral region of the photosensitive element region is refracted through the first beveled surface towards the photosensitive element region.

14. The method as claimed in claim 13, wherein an angle between the first beveled surface and a surface of the substrate is smaller than an angle between a diagonal of the photosensitive element region and a direction perpendicular to the substrate surface.

15. The method as claimed in claim 13 wherein:
the first light concentrating portion and the peripheral region at least partially coincide with each other from a view along a direction perpendicular to a main surface of the substrate, and
the first beveled surface of the first light concentrating portion is inclined downwards and outwards, a bottom edge of the beveled surface is located in the peripheral region, and a top edge or a vertex of the beveled surface is located at a boundary of the photosensitive element region, above the boundary of the photosensitive element region, or above the photosensitive element region.

16. The method as claimed in claim 11, further comprising:
forming a second light concentrating portion above the photosensitive element region, the second light concentrating portion including a second beveled surface configured to cause light incident on the beveled surface refracted towards the photosensitive element region.

17. The method as claimed in claim 16, wherein
the second light concentrating portion at least partially coincides with the photosensitive element region and the peripheral region from a view along a direction perpendicular to the main surface of the substrate, and
wherein the second beveled surface at least partially covers the peripheral region in a projection perpendicular to the direction of the main plane.

18. The method as claimed in claim 16, wherein the second light concentrating portion is formed on the substrate, and
a refractive index of the second light concentrating portion is greater than or equal to a refractive index of the portion of the substrate that is contact with the second light concentrating portion.

19. The method as claimed in claim 16, further comprising:
forming a filling layer including a color filter function on the second light concentrating portion, wherein the filling layer at least partially covers a surface of the second light concentrating portion,
wherein, a refractive index of the filling layer is smaller than a refractive index of the second light concentrating portion.

20. An image forming device comprising the image sensor as claimed in claim 1.
